(19) United States
(12) Patent Application Publication
(10) Pub. No.: US 2015/0246447 A1
(43) Pub. Date: Sep. 3, 2015

(54) SUCTION PAD, ROBOT HAND AND ROBOT

(71) Applicant: KABUSHIKI KAISHA YASKAWA DENKI, Kitakyushu-shi (JP)

(72) Inventors: Masatoshi FURUICHI, Fukuoka (JP); Ryuji ANDO, Fukuoka (JP)

(73) Assignee: KABUSHIKI KAISHA YASKAWA DENKI, Kitakyushu-shi (JP)

(21) Appl. No.: 14/620,186

(22) Filed: Feb. 12, 2015

(30) Foreign Application Priority Data
Feb. 28, 2014 (JP) 2014-039080

(51) Int. Cl. B25J 15/06; B65G 49/06; H01L 21/683

(52) U.S. Cl. CPC B25J 15/0616; H01L 21/6838; B65G 49/061

(57) ABSTRACT

A suction pad includes a pad portion for holding a target object by suction and having a first and a second connection end portion; and a first and a second fixing portion provided at positions spaced apart from the pad portion so as to be opposite to each other across the pad portion to fix the pad portion. The suction pad further includes a first support portion having an extension length larger than a spaced-apart distance between the pad portion and the first fixing portion and connecting the first connection end portion to the first fixing portion; and a second support portion having an extension length larger than a spaced-apart distance between the pad portion and the second fixing portion and connecting the second connection end portion to the second fixing portion.

### CROSS-REFERENCE TO RELATED APPLICATION

The present disclosure contains subject matter related to that disclosed in Japanese Priority Patent Application No. 2014-039080 filed with the Japan Patent Office on Feb. 28, 2014, the entire contents of which are incorporated herein by reference.

### BACKGROUND OF THE INVENTION

1. Field of the Invention

An embodiment disclosed herein relates to a suction pad, a robot hand and a robot.

2. Description of the Related Art

In the related art, there is known a substrate transfer device that transfers a thin substrate such as a wafer or a glass substrate.

The substrate transfer device includes, e.g., a robot arm. The substrate transfer device transfers a substrate by moving the robot arm in a horizontal direction or other directions, while holding the substrate with a robot hand provided at a tip portion of the robot arm.

In the course of transferring the substrate, it is necessary to reliably hold the substrate and to prevent position shift of the substrate. Thus, there is proposed a robot which includes a vacuum-suction-type suction pad provided at a robot hand and which transfers a substrate while holding a substrate by suction through the suction pad (see, e.g., Japanese Patent Application Publication No. 2007-53313).

### SUMMARY OF THE DISCLOSURE

In accordance with an aspect of the disclosure, there is provided a suction pad which includes a pad portion for holding a target object by suction and having a peripheral edge portion provided with a first connection end portion and a second connection end portion which are positioned to be opposite to each other across a center of the pad portion, the first connection end portion, the second connection end portion and the center being arranged on a straight line, and a first and a second fixing portion provided at positions spaced apart from the pad portion so as to be opposite to each other across the pad portion and configured to fix the pad portion. The suction pad further includes a first support portion having an extension length larger than a spaced-apart distance between the pad portion and the first fixing portion, the first support portion being configured to connect the first connection end portion with the first fixing portion, and a second support portion having an extension length larger than a spaced-apart distance between the pad portion and the second fixing portion, the second support portion being configured to connect the second connection end portion with the second fixing portion.

### BRIEF DESCRIPTION OF THE DRAWINGS

FIG. 1 is a perspective view of a robot according to an embodiment.

FIG. 2 is a schematic plan view of a hand.

FIG. 3A is a schematic plan view of a suction pad.

FIG. 3B is a schematic sectional view taken along line A-A′ in FIG. 3A.

FIGS. 4A and 4B are schematic sectional views showing an attachment structure of a suction pad.

FIGS. 5A and 5B are schematic sectional views showing a modified example of a fixing portion.

FIG. 6A is a schematic plan view showing an arrangement example of the suction pad.

FIG. 6B is a schematic plan view showing the movement of the suction pad.

FIG. 7 is a schematic plan view of a suction pad according to a first modified example.

FIG. 8 is a schematic plan view of a suction pad according to a second modified example.

### DESCRIPTION OF THE EMBODIMENT

An embodiment of a suction pad, a robot hand and a robot disclosed herein will now be described in detail with reference to the accompanying drawings. The present disclosure is not limited to the embodiment to be described below.

Hereinafter, description will be made by taking, as an example, a case where the robot is a substrate transfer robot for transferring a wafer as an object to be transferred. The wafer is designated by reference symbol “W”. In the following description, each of the rigid elements which constitute a mechanical structure and which can make movement relative to each other will be referred to as a “link”. The “link” will be often referred to as an “arm”. In addition, the robot hand will be referred to as a “hand”.

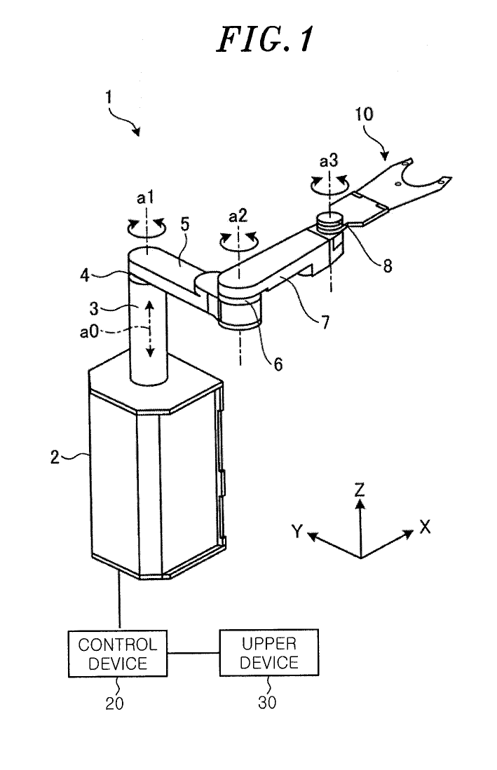

First, the configuration of a robot 1 according to an embodiment will be described with reference to FIG. 1. FIG. 1 is a perspective view of a robot 1 according to an embodiment.

For the sake of making the description readily understandable, a three-dimensional rectangular coordinate system including a Z-axis whose positive direction extend vertically upward and whose negative direction extends vertically downward is indicated in FIG. 1. The direction extending along an X-Y plane designates a “horizontal direction”. This rectangular coordinate system is sometimes indicated in other drawings used in the following description.

In the following description, for the purpose of convenience in description, the positional relationship between the respective parts of the robot 1 will be described under the assumption that the swing position of the robot 1 and the orientation of fingers are in the states shown in FIG. 1.

In the following description, it is sometimes the case that only some of a plurality of components are designated by reference symbols with the remaining components not given any reference symbol. In this case, it is assumed that some of the components accompanying reference symbols are identical in configuration with the remaining components.

As shown in FIG. 1, the robot 1 includes a base 2, a lifting/lowering unit 3, a first joint unit 4, a first arm 5, a second joint unit 6, a second arm 7, a third joint unit 8 and a hand 10. The first arm 5 and the second arm 7 constitute an arm unit.

The base 2 is a base unit of the robot 1 and is fixed to a floor surface or a wall surface. In some cases, the base unit is fixed to another device through the upper surface thereof. The lifting/lowering unit 3 is installed so that it can slide in a vertical direction (a Z-axis direction) with respect to the base 2 (see a double-head arrow a0 in FIG. 1). The lifting/lowering unit 3 moves the arm unit of the robot 1 up and down along the vertical direction.

The first joint unit 4 is a rotary joint for rotating about an axis a1. The first arm 5 is rotatably connected to the lifting/lowering unit 3 through the first joint unit 4 (see a double-head arrow around the axis a1 in FIG. 1).

The second joint unit 6 is a rotary joint for rotating about an axis a2. The second arm 7 is rotatably connected to the first arm 5 through the second joint unit 6 (see a double-head arrow around the axis a2 in FIG. 1).

The third joint unit 8 is a rotary joint for rotating about an axis a3. The hand 10 is rotatably connected to the second arm 7 through the third joint unit 8 (see a double-head arrow around the axis a3 in FIG. 1).

The robot 1 is equipped with a drive source (not shown) such as a motor or the like. Each of the first joint unit 4, the second joint unit 6 and the third joint unit 8 is rotated by the operation of the drive source.

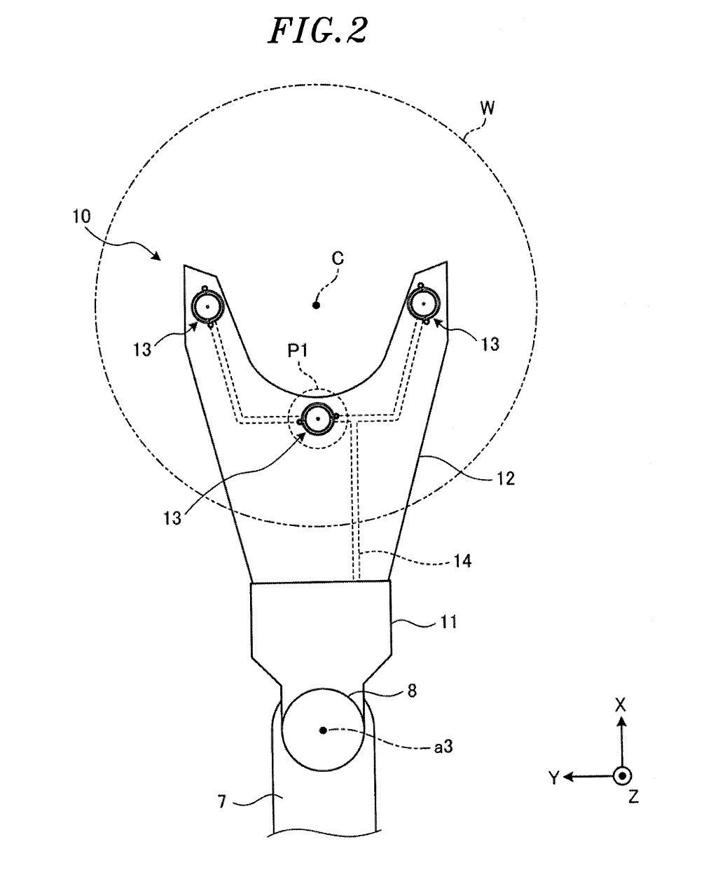

The hand 10 is an end effector that vacuum-sucks and holds a wafer W. Details of the configuration of the hand 10 will be described later with reference to FIG. 2 and the ensuing figures. In FIG. 1, there is shown a case where the robot 1 is provided with one hand 10. However, the number of the hand 10 is not limited thereto.

For example, a plurality of hands 10 may be installed in an overlapping relationship about the axis a3 so that the hands 10 can independently rotate about the axis a3.

The robot 1 transfers a wafer W using the combination of the up and down operation of the lifting/lowering unit 3 and the rotating operations of the respective arms 5 and 7 and the hand 10. These operations are executed by instructions from a control device 20 which is connected to the robot 1 through a communication network so that they can make communication with each other.

The control device 20 is a controller that controls operations of the robot 1. For instance, the control device 20 instructs the operation of the aforementioned drive source. Responsive to the instructions transmitted from the control device 20, the robot 1 rotates the drive source by an arbitrary angle, thereby rotating the arm unit.

This operation control is executed based on teaching data pre-stored in the control device 20. However, in a case where the control device 20 is connected to an upper device 30 in a manner that they can make communication with each other, the teaching data may be obtained from the upper device 30.

Next, the configuration of the hand 10 will be described with reference to FIG. 2. FIG. 2 is a schematic plan view of the hand 10. In FIG. 2, the wafer W existing in a prescribed position is indicated by a double-dot chain line. The center of the wafer W existing in the prescribed position is designated by reference symbol “C”.

As shown in FIG. 2, the hand 10 is installed in the tip portion of the second arm 7 through the third joint unit 8 so as to rotate about the axis a3. The hand 10 includes a plate support portion 11, a plate 12, suction pads 13 and a vacuum path 14.

The plate support portion 11 is connected to the third joint unit 8 and is configured to support the plate 12. The plate 12 is a member serving as a base of the hand 10 and is made of ceramic or the like. In FIG. 2, there is illustrated the plate 12 whose tip portion has a bifurcated shape. However, the shape of the plate 12 is not limited thereto.

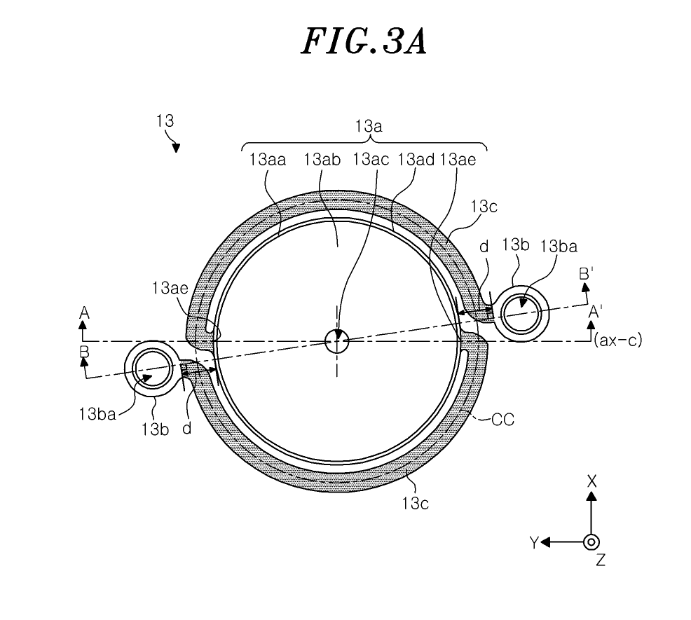

The suction pads 13 are members that vacuum-suck and hold the wafer W on the hand 10. In the present embodiment, three suction pads 13 are installed in the positions shown in FIG. 2 and are configured to hold the wafer W by suction at three points. The number of the suction pads 13 is not limited thereto but may be, e.g., more than three. The configuration of each of the suction pads 13 will be described in detail with reference to FIG. 3A and the ensuing figures.

The vacuum path 14 is a suction route that extends from the respective suction pads 13 to a vacuum source (not shown). For example, as shown in FIG. 2, the vacuum path 14 is formed within the plate 12. As the wafer W is placed on the suction pads 13, the vacuum source performs evacuation through the vacuum path 14 and causes the suction pads 13 to hold the wafer W by suction. The vacuum path 14 may be formed in any position insofar as the vacuum path 14 enables the vacuum source to perform suction.

Examples of the shape of a warp generated in the wafer W includes a so-called “dome shape” in which the wafer W is gradually raised over the center C, a so-called “bowl shape” in which the wafer W is gradually depressed over the center C, and a “random shape” in which the wafer W has the dome shape and the bowl shape in combination. However, in reality, it will be sufficient to assume that one of the “dome shape” and the “bowl shape” is generated in the local area of the wafer W corresponding to each of the suction pads 13. For that reason, the behavior of each of the suction pads 13 will now be described by taking, as an example, a case where the warp of the wafer W has the “dome shape” or the “bowl shape”.

That is to say, it can be said that the wafer W takes a warped shape having a bending direction extending in a radial direction. In the present embodiment, even if the wafer W is warped, the suction pads 13 are caused to conform to the wafer W, thereby reliably holding the wafer W by vacuum-suction.

Next, the configuration of each of the suction pads 13 will be described in detail. In the following description, among the suction pads 13 shown in FIG. 2, only the pad 13 surrounded by a dotted circle P1 will be taken as a primary example.

FIG. 3A is a schematic plan view of the suction pad 13. FIG. 3B is a schematic sectional view taken along line A-A′ in FIG. 3A. As shown in FIGS. 3A and 3B, the suction pad 13 includes a pad portion 13a, a pair of fixing portions 13b and a pair of support portions 13c. In order to illustrate the respective portions in an easily understandable manner, the support portions 13c seen in a plan view are indicated in a shaded pattern (see FIG. 3A).

The suction pad 13 may be made of various kinds of materials such as a resin and the like. For example, the material of the suction pad 13 preferably has flexibility so that the suction pad 13 can conform to the warped wafer W.

Since there is a likelihood that the suction pad 13 makes contact with the wafer W in a high temperature state, it is preferred that the suction pad 13 is superior in heat resistance. As one example, a polyimide resin or the like may be suitably used as the material of the suction pad 13. In the present embodiment, it is assumed that the suction pad 13 is one-piece molded through the use of a polyimide resin.

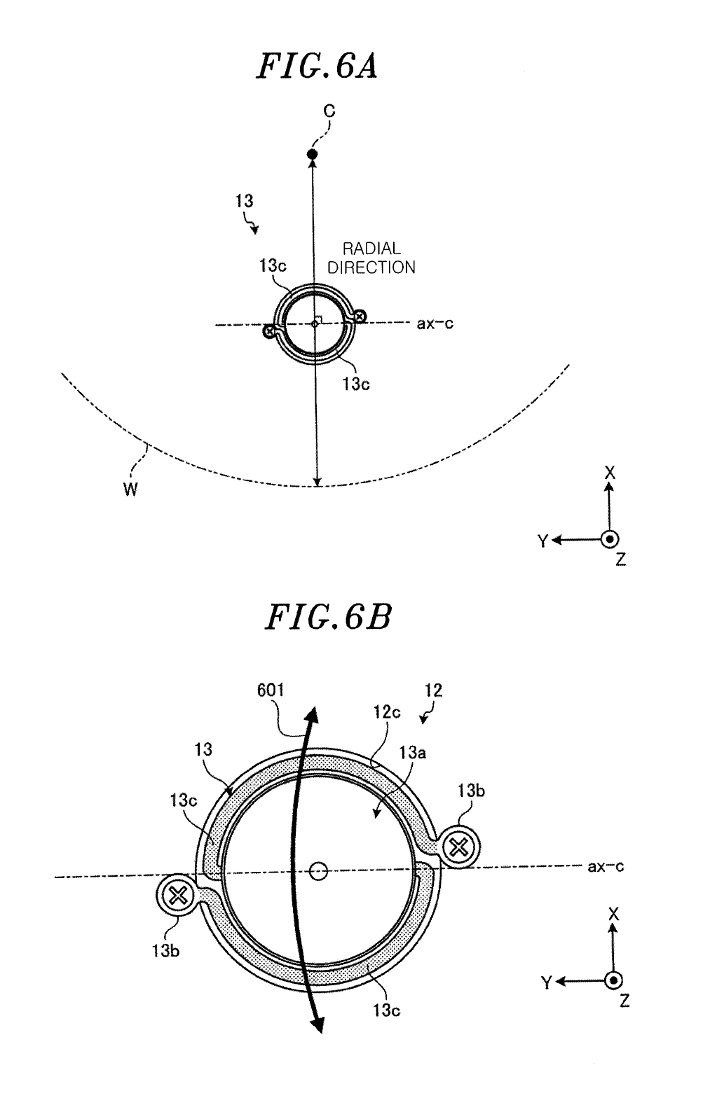

The pad portion 13a is a portion for holding a target object by suction. The pad portion 13a includes a contact portion 13aa, a major surface portion 13ab, a suction hole 13ac and a peripheral edge portion 13ad. The pad portion 13a further includes connection end portions 13ae provided in the peripheral edge portion 13ad to which the support portions 13c are connected as will be described later. The contact portion 13aa is a portion which makes contact with the wafer W, i.e., a target object. The major surface portion 13ab is a portion which serves as a so-called base plate of the suction pad 13. The outer periphery of the major surface portion 13ab is surrounded by the contact portion 13aa. Although the major surface portion 13ab having a substantially circular shape is illustrated in FIG. 3A, the shape of the major surface portion 13ab is not limited thereto. In this regard, a modified example is shown in FIG. 7 and will be described later.

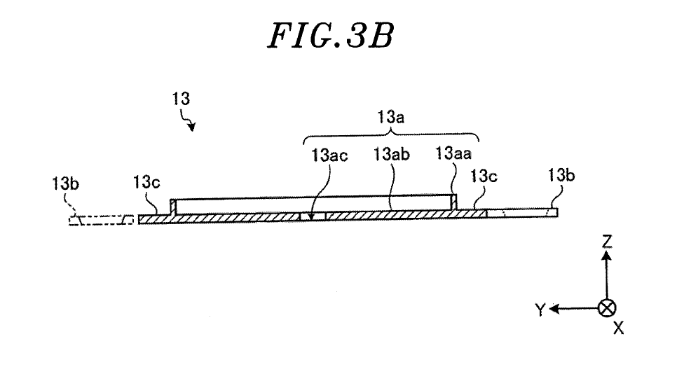

The suction hole 13ac is formed in the central region of the major surface portion 13ab. The suction hole 13ac allows the space surrounded by the contact portion 13aa to communicate with the vacuum source through a seal member 15 (see FIG. 4A or 4B) to be described later.

The fixing portions 13b are installed in positions spaced apart from the pad portion 13a so as to face each other across the pad portion 13a. The fixing portions 13b are a pair of portions for fixing the pad portion 13a. Each of the fixing portions 13b has a through-hole 13ba into which a fastening member SC (to be described later) such as a bolt or a screw is inserted. While the fixing portions 13b having a substantially circular shape are illustrated in FIG. 3A, the shape of the fixing portions 13b is not limited thereto.

The support portions 13c are installed in pair and are configured to interconnect the connection end portions 13ae existing on a center axis line ax-c′ of the pad portion 13a and the fixing portions 13b. Each of the support portions 13c has an “extension length” larger than the spaced-apart distance d between the pad portion 13a and each of the fixing portions 13b. The term “extension length” used herein refers to the length which extends along the shape of an outline from one end to the other end of each of the support portions 13c.

For example, FIG. 3A shows one example of the “extension length” larger than the spaced-apart distance d. As shown in FIG. 3A, each of the support portions 13c is installed so as to go around and extend along the outer circumference of the pad portion 13a. One end of each of the support portions 13c is connected to one of the connection end portions 13ae. The other end of each of the support portions 13c is connected to the fixing portion 13b existing at the side of the other connection end portion 13ae.

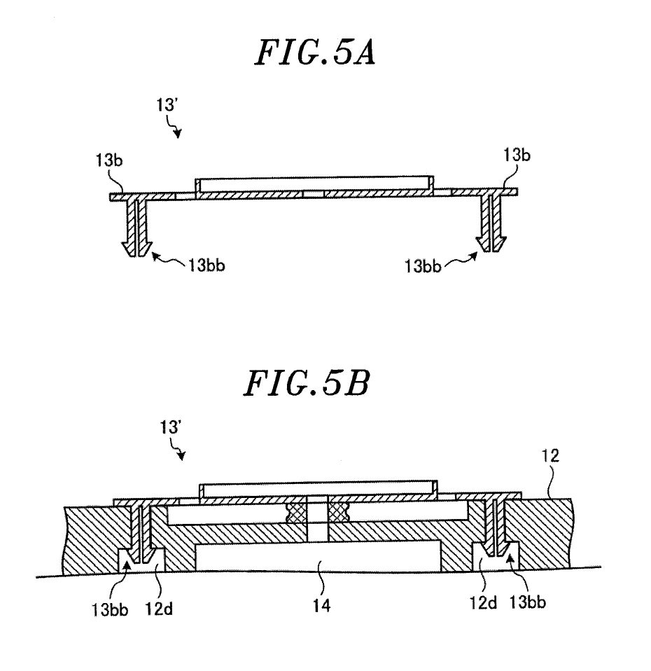

In this case, if the pad portion 13a has a substantially circular shape as shown in FIG. 3A, it is preferred that each of the support portions 13c is installed to extend substantially along one half of a circumference of the pad portion 13a while not making contact with the region of the pad portion 13a other than the connection end portions 13ae. This makes it possible to increase the “extension length” of each of the support portions 13c. By increasing the “extension length”, it is possible to increase the elasticity of each of the support portions 13c, thereby allowing the suction pad 13 to be easily deformed in conformity with the shape of a wafer W. On this point, description will be made later with reference to FIG. 6B.

The support portions 13c are preferably installed on the circumference of the same circle CC. Specifically, as shown in FIG. 3A, the support portions 13c are installed to extend respectively from the connection end portions 13ae existing on the center axis line ax-c of the pad portion 13a. In contrast, the fixing portions 13b are disposed on a center axis line (see line B-B′ in FIG. 3A) differing from the center axis ax-c. The term “center axis line” used herein refers to a straight line through which passes through the connection end portions 13ae and the center of the pad portion 13a and which extends in a direction parallel to a suction surface of the object to be held by suction. Since the support portions 13c can be installed in close proximity with the outer periphery of the pad portion 13a in this way, it is possible to form the entire contour of the suction pad 13 into a substantially circular compact shape.

Next, description will be made on an attachment structure of the suction pad 13. FIGS. 4A and 4B are schematic sectional views showing an attachment structure of the suction pad 13. The schematic cross section shown in FIGS. 4A and 4B corresponds to the cross section taken along line B-B′ in FIG. 3A.

As shown in FIG. 4A, a suction hole 12a leading to the vacuum path 14, hole portions 12b corresponding to the fastening members SC and the through-holes 13ba, and an annular wall portion 12c are formed in the plate 12 in advance. That is to say, the plate 12 is a fixing base of the suction pad 13 according to the present embodiment.

The seal member 15 is installed between the suction pad 13 and the plate 12. The seal member 15 is an elastic body having a substantially annular shape and is made of, e.g., a silicon resin. The seal member 15 is formed so as to have a height h1 which is larger than a gap h2 between the suction pad 13 and the plate 12 available when the suction pad 13 is attached to the plate 12.

As shown in FIGS. 4A and 4B, the suction pad 13 is attached to the plate 12 by inserting the fastening members SC passed through the through-holes 13ba into the hole portions 12b while aligning the outer circumference of the suction hole 13ac, the inner circumference of the seal member 15 and the outer circumference of the suction hole 12a with one another.

Use of the fastening members SC makes it possible to attach the suction pad 13 to the plate 12 without having to use an adhesive agent. Accordingly, it is possible to obtain an effect of preventing organic substances contained in an adhesive agent from being volatilized and affecting a product when a wafer W is kept at a high temperature. As shown in FIGS. 4A and 4B, it is preferred that each of the fastening members SC is a countersunk screw or a low-head bolt whose head portion has a flat top surface. By using the fastening members SC whose head portion has a flat top surface, it is possible to prevent the fastening members SC from interfering with a wafer W.

Since the seal member 15 has a height h1 which is larger than a gap h2 between the suction pad 13 and the plate 12, the seal member 15 is compressed in a crushed state. This makes it possible to reliably seal a clearance between the suction holes 13ac and 12a, thereby securing an air-tight space.

When the suction pad 13 is attached in this way, a space is formed below the support portions 13c. This is because the annular wall portion 12c is formed to have an inner diameter larger than an outer diameter of a substantially annular shape of the support portions 13c. This makes it possible to apply elasticity to the support portions 13c by keeping free the support portions 13c extending from one end to the other end thereof. Thus, the suction pad 13 can be easily deformed in conformity with the shape of a wafer W.

While a case where the pad portion 13a is supported on the plate 12 using the seal member 15 has been taken as an example, the present disclosure is not limited thereto. For example, the pad portion 13a may be supported by an annular support portion (not shown) annularly erected along the periphery of the suction hole 12a of the plate 12.

While there has been taken an attachment example which makes use of the fastening members SC, the fixing portions 13b may be configured so that the suction pad 13 can be attached to the plate 12 without having to use the fastening members SC. Now, description will be made on a modified example of the fixing portions 13b.

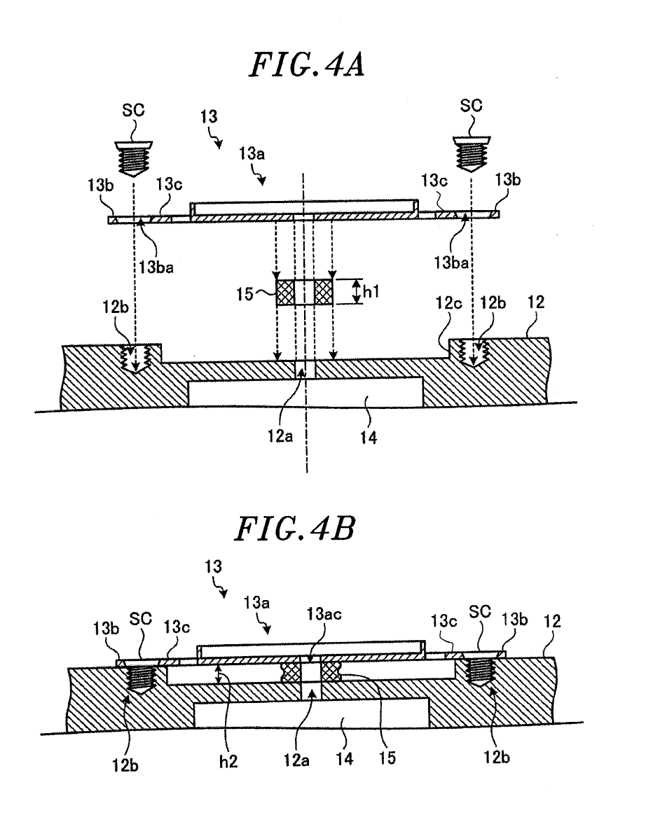

FIGS. 5A and 5B are schematic sectional views showing a modified example of the fixing portions 13b. The schematic cross section shown in FIGS. 5A and 5B corresponds to the cross section taken along line B-B′ in FIG. 3A. In FIGS. 5A and 5B, the suction pad is designated by a reference numeral “13′”.

As shown in FIG. 5A, each of the fixing portions 13b of the suction pad 13′ according to the modified example includes a split-end pin portion 13bb which protrudes toward the plate 12 and which includes a split-end head portion having claws serving as barbs. The split-end pin portion 13bb preferably has elasticity such that the split-end pin portion 13bb can be expanded outward in a free state.

As shown in FIG. 5B, in conformity with the shape of the suction pad 13′, through-holes 12d shaped to engage with the barbs of the head portions of the split-end pin portions 13bb are previously formed in the plate 12.

The suction pad 13′ is attached to the plate 12 by inserting the split-end pin portions 13bb into the through-holes 12d. Since the split-end pin portions 13bb have elasticity so as to be expanded in a free state and have the barbs formed in the head portions thereof, the suction pad 13′ can be fastened to the plate 12 without having to use a tool. That is to say, the suction pad 13′ can be attached to the plate 12 with ease. This enables an end user to efficiently perform a pad replacing work on the spot.

Just like the case where the fastening members SC are used, the suction pad 13′ can be attached to the plate 12 without having to use an adhesive agent. It is therefore possible to prevent organic substances contained in an adhesive agent from being volatilized and affecting a product.

Turning back to the description of the suction pad 13, an arrangement example of the suction pad 13 and the movement thereof will now be described. FIG. 6A is a schematic plan view showing an arrangement example of the suction pad 13. FIG. 6B is a schematic plan view showing the movement of the suction pad 13.

As shown in FIG. 6A, for example, the suction pad 13 is disposed such that the center axis ax-c on which one ends of the support portions 13c exist is substantially orthogonal to the radial direction of a wafer W existing in a prescribed position. In other words, the suction pad 13 is disposed such that the center axis ax-c is oriented in a tangential direction of a concentric circle virtually drawn about the center C of the wafer W existing in the prescribed position.

By virtue of this arrangement, as shown in FIG. 6B, it is possible to easily tilt the suction pad 13 about the center axis ax-c substantially orthogonal to the radial direction of the suction pad 13 (see an arrow 601 in FIG. 6B). That is to say, it is possible to make the suction pad 13 easily conform to the wafer W which is easy to take a form warped in the radial direction, such as a dome shape or a bowl shape.

As described above and as shown in FIG. 6B, each of the support portions 13c of the suction pad 13 has an “extension length” larger than the spaced-apart distance d between the pad portion 13a and each of the fixing portions 13b (see FIG. 3A). Thus, the suction pad 13 is installed in a so-called floating state in a space defined by the annular wall portion 12c.

For that reason, the support portions 13c are given elasticity larger than that available when the pad portion 13a and the fixing portions 13b are directly connected at a length equal to the spaced-apart distance d. Consequently, the support portions 13c support the entirety of the suction pad 13 in a so-called easily movable state.

In other words, the support portions 13c of the suction pad 13 according to the present embodiment are configured so that the suction pad 13 can be easily twisted about the center axis ax-c by the elasticity given to the support portions 13c. The flexibility of the suction pad 13 and the elasticity of the seal member 15 act in generating a torsional force at this time. This enables the suction pad 13 to make tilting movement with ease.

Accordingly, even if the wafer W is warped, the suction pad 13 can easily conform to the wafer W. That is to say, it is possible to reliably hold the wafer W by suction.

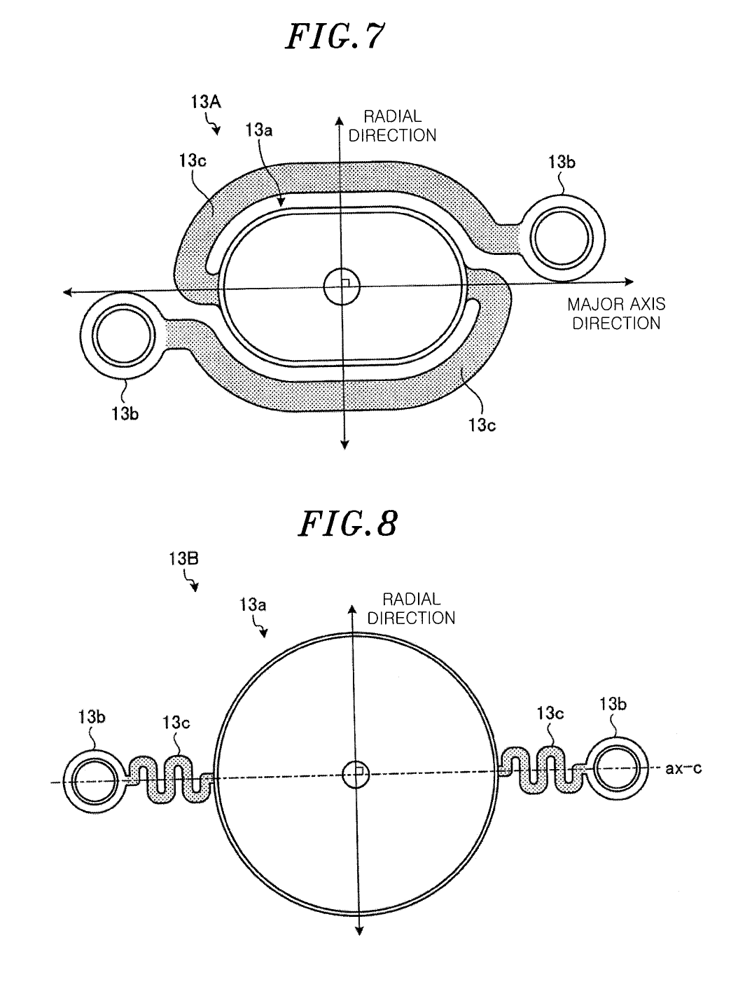

The shape of the suction pad 13 is not limited to the example described thus far. Next, modified examples of the suction pad 13 will be described with reference to FIGS. 7 and 8. The modified example shown in FIG. 7 is a first modified example. The modified example shown in FIG. 8 is a second modified example.

FIG. 7 is a schematic plan view of a suction pad 13A according to the first modified example. The suction pad 13A according to the first modified example differs from the suction pad 13 described above in that the pad portion 13a is formed into a substantially rounded rectangular shape and the support portions 13c are installed to extend along a rounded rectangular circumference larger than the outer circumference of the pad portion 13a.

In case of this suction pad 13A, it is preferred that the suction pad 13A is installed such that a major axis thereof extends along the center axis ax-c described above. This enables the suction pad 13A to effectively conform, in a minor axis direction, to the wafer W which takes a warp form having a warp direction extending in a radial direction, such as a dome shape or a bowl shape.

Specifically, it can be said that a so-called wafer W has a small warp amount in a direction substantially orthogonal to the radial direction and has a large warp amount in the radial direction. If the minor axis direction of the suction pad 13A is arranged to extend along the radial direction, the warp amount of the wafer W becomes smaller on the suction pad 13A. That is to say, the suction pad 13A can conform to the wafer W without having to move largely. Accordingly, leak is hardly generated during vacuum suction. This makes it possible to reliably hold the wafer W by suction.

While there has been taken an example in which the support portions 13c are installed so as to go around and extend along the outer circumference of the pad portion 13a, the support portions 13c may not go around and extend along the outer circumference of the pad portion 13a. FIG. 8 is a schematic plan view of a suction pad 13B according to the second modified example.

As shown in FIG. 8, each of the support portions 13c may have a serpentine shape when seen in a plan view and may connect the connection end portions 13ae of the pad portion 13a located on the center axis ax-c to the fixing portions 13a at the side of (or near) the respective connection end portions 13ae.

Even in this case, each of the support portions 13c has an “extension length” larger than the spaced-apart distance d between the pad portion 13a and each of the fixing portions 13b (see FIG. 3A). It is therefore possible to obtain elasticity larger than that available when the pad portion 13a and each of the fixing portions 13b are connected to each other at the spaced-apart distance d. That is to say, even if the wafer W is warped, the suction pad 13B can easily conform to the wafer W and can reliably hold the wafer W by suction.

As described above, the suction pad according to the present embodiment includes a pad portion, a pair of fixing portions and a pair of support portions. The pad portion holds a target object by suction. The fixing portions are installed at positions spaced apart from the pad portion so as to face each other across the pad portion. The fixing portions serve as fixing ends for fixing the pad portion.

Each of the support portions has an extension length larger than a spaced-apart distance between the pad portion and each of the fixing portions. Each of the support portions interconnects each of connection end portions of the pad portion existing on a center axis and each of the fixing portions.

According to the suction pad of the present embodiment, the robot hand provided the suction pad, and the robot provided with the robot hand, it is possible to reliably hold a substrate by suction even when the substrate is warped.

As an example, in case of the split-end pin portion described in the aforementioned embodiment, a conductor may be drawn from the plate support portion. This can contribute to prevention of static charge of a wafer. It is therefore possible to prevent particles or the like from adhering to the wafer.

In the embodiment described above, the substantially rounded rectangular shape is taken as an example of the shape of the major surface portion of the pad portion. Alternatively, the shape of the major surface portion may be an oval shape which includes an elliptical shape.

In the embodiment described above, there has been described a single-arm robot by way of example. However, the present disclosure may be applied to a dual-arm robot or a multi-arm robot.

In the embodiment described above, there has been described an example where the target object is a wafer. However, the target object is not limited thereto but may be any thin substrate. In this regard, the kind of the substrate does not matter. The substrate may be, e.g., a glass substrate for a liquid crystal panel display.

In case of the glass substrate, the aforementioned radial direction refers to a radial direction of a concentric circle virtually drawn about the center of the target object or a direction radially extending from the center of the target object. The target object may not be a substrate as long as it is a thin workpiece.

In the embodiment described above, description has been made by taking, as an example, a case where the robot is a substrate transfer robot for transferring a substrate such as a wafer or the like. However, the robot may be a robot for performing a work other than a transfer work. For example, the robot may be an assembling robot that performs a specified assembling work while holding a thin workpiece by vacuum-suction through the use of a hand provided with a suction pad.

It should be understood by those skilled in the art that various modifications, combinations, sub-combinations and alterations may occur depending on design requirements and other factors insofar as they are within the scope of the appended claims or the equivalents thereof.

What is claimed is:

1. A suction pad comprising:
a pad portion configured to hold a target object by suction and having a peripheral edge portion provided with a first connection end portion and a second connection end portion which are positioned to be opposite to each other across a center of the pad portion, the first connection end portion, the second connection end portion and the center being arranged on a straight line;
a first and a second fixing portion provided at positions spaced apart from the pad portion so as to be opposite to each other across the pad portion and configured to fix the pad portion;
a first support portion having an extension length larger than a spaced-apart distance between the pad portion and the first fixing portion, the first support portion being configured to connect the first connection end portion with the first fixing portion; and
a second support portion having an extension length larger than a spaced-apart distance between the pad portion and the second fixing portion, the second support portion being configured to connect the second connection end portion with the second fixing portion.

2. The suction pad of claim 1, wherein the first support portion and the second support portion extend along the peripheral edge portion at an outer side of the pad portion, and wherein the first fixing portion is positioned closer to the second connection end portion than the first connection end portion, and the second fixing portion is positioned closer to the first connection end portion than the second connection end portion.

3. The suction pad of claim 2, wherein the pad portion has a substantially circular shape, each of the first support portion and the second support portion extending along a half of the peripheral edge portion of the pad portion.

4. The suction pad of claim 3, wherein the first support portion and the second support portion extend along the peripheral edge portion of the pad portion without overlapping each other.

5. The suction pad of claim 2, wherein the pad portion has a substantially oval shape, the straight line extending along a major axis of the pad portion.

6. The suction pad of claim 1, wherein the first support portion and the second support portion extend while intersecting the straight line multiple times when seen in a plan view, and wherein the first fixing portion is positioned closer to the first connection end portion and the second fixing portion is positioned closer to the second connection end portion.

7. The suction pad of claim 1, wherein the pad portion is disposed such that the straight line extends in a direction substantially orthogonal to a radial direction extending from a center of the target object to pass over the pad portion.

8. The suction pad of claim 2, wherein the pad portion is disposed such that the straight line extends in a direction substantially orthogonal to a radial direction extending from a center of the target object to pass over the pad portion.

9. The suction pad of claim 3, wherein the pad portion is disposed such that the straight line extends in a direction substantially orthogonal to a radial direction extending from a center of the target object to pass over the pad portion.

10. The suction pad of claim 4, wherein the pad portion is disposed such that the straight line extends in a direction substantially orthogonal to a radial direction extending from a center of the target object to pass over the pad portion.

11. The suction pad of claim 5, wherein the pad portion is disposed such that the straight line extends in a direction substantially orthogonal to a radial direction extending from a center of the target object to pass over the pad portion.

12. The suction pad of claim 6, wherein the pad portion is disposed such that the straight line extends in a direction substantially orthogonal to a radial direction extending from a center of the target object to pass over the pad portion.

13. A robot hand comprising the suction pad of claim 1.

14. A robot hand comprising the suction pad of claim 2.

15. A robot hand comprising the suction pad of claim 3.

16. A robot hand comprising the suction pad of claim 4.

17. A robot comprising the robot hand of claim 13.

18. A robot comprising the robot hand of claim 14.

19. A robot comprising the robot hand of claim 15.

20. A robot comprising the robot hand of claim 16.
